(19) United States
(12) Patent Application Publication
(10) Pub. No.: US 2007/0015343 A1
(43) Pub. Date: Jan. 18, 2007

(54) Method for dicing a semiconductor wafer

(75) Inventors: Kuan-Jen Chung, Tainan Hsien (TW); Fu-Yao Yang, Tainan Hsien (TW); Williams Tsau, Tainan Hsien (TW); Chih-Hao Lin, Tainan Hsien (TW); Kun-Yu Lai, Tainan Hsien (TW)

Correspondence Address: FOLEY AND LARDNER LLP;SUITE 500, 3000 K STREET NW, WASHINGTON, DC, 20007, US

(73) Assignee: GENESIS PHOTONICS INC.

(21) Appl. No.: 11/182,794

(22) Filed: Jul. 18, 2005

(51) Int. Cl. H01L 21/00

(52) U.S. Cl. 438/462; 257/E21.238

(57) ABSTRACT

A method for dicing a semiconductor wafer includes the steps of: forming grooves in an integrated circuit layer of the semiconductor wafer; forming a photoresist layer on the integrated circuit layer; forming V-shaped first notches, each of which is further indented from the integrated circuit layer; thinning the substrate; attaching a blue tape to the integrated circuit layer; forming V-shaped second notches, each of which is indented from the thinned substrate and each of which is registered with a respective one of the first notches such that the first and second notches cooperatively define imaginary breaking lines, respectively; and pressing the blue tape at positions that are aligned with the imaginary breaking lines, respectively.

### BACKGROUND OF THE INVENTION

1. Field of the Invention

This invention relates to a method for dicing a semiconductor wafer, more particularly to a method involving formation of first notches in an integrated circuit layer and second notches in a substrate of the semiconductor wafer prior to dicing operation.

2. Description of the Related Art

Taiwanese patent no. I223216 discloses a method for dicing a light emitting diode (LED) semiconductor wafer. The method involves forming trenches in a semiconductor side and an opposite underside of the wafer for facilitating breaking of the wafer into LED dices. Since the trenches formed in the semiconductor side of the wafer extend down to the substrate, the time required for forming the trenches using laser cutting techniques is relatively long. In addition, the light extraction efficiency of the dices thus formed tends to be adversely affected when exposed to the laser for a long periods of time. Moreover, undesired cracks are still likely to occur and propagate along edges of the dices as a result of breaking of the semiconductor wafer into the dices, which also has an adverse effect on the light extraction efficiency of the dices.

### SUMMARY OF THE INVENTION

The object of the present invention is to provide a method for dicing a semiconductor wafer that is capable of overcoming the aforesaid drawbacks of the prior art.

According to the present invention, there is provided a method for dicing a semiconductor wafer having a substrate and an integrated circuit layer formed on the substrate. The substrate has opposite inner and outer surfaces. The integrated circuit layer has an inner surface attached to the inner surface of the substrate, and an outer surface opposite to the inner surface of the integrated circuit layer. The method comprises: forming elongated grooves that are indented from the outer surface of the integrated circuit layer in a transverse direction relative to the semiconductor wafer, each of the elongated grooves being defined by a groove-defining wall; forming a photoresist layer on the outer surface of the integrated circuit layer; forming elongated first notches, each of which extends through the photoresist layer and is further indented from the groove-defining wall of a respective one of the grooves in the transverse direction such that each of the first notches is spaced apart from the inner surface of the substrate by a predetermined thickness; removing the photoresist layer from the semiconductor wafer; thinning the substrate from the outer surface of the substrate; attaching a blue tape to the outer surface of the integrated cirucit layer; forming elongated second notches, each of which is indented from the outer surface of the thinned substrate in the transverse direction and each of which is registered with a respective one of the first notches in the transverse direction such that the first and second notches cooperatively define imaginary breaking lines, respectively; and pressing the blue tape at positions that are aligned with the imaginary breaking lines, respectively, so as to break the semiconductor wafer into dices. Each of the first notches has a V-shaped cross-section, and each of the second notches has an inverted V-shaped cross-section so as to permit sharp cleaving of the semiconductor wafer along the imaginary breaking lines to reduce the extent of formation of cracks propagating along edges of the dices thus formed.

### BRIEF DESCRIPTION OF THE DRAWINGS

In drawings which illustrate an embodiment of the invention,

FIGS. 1 to 8 are fragmentary schematic sectional views to illustrate consecutive steps of the preferred embodiment of a method for dicing a semiconductor wafer according to the present invention.

### DETAILED DESCRIPTION OF THE PREFERRED EMBODIMENT

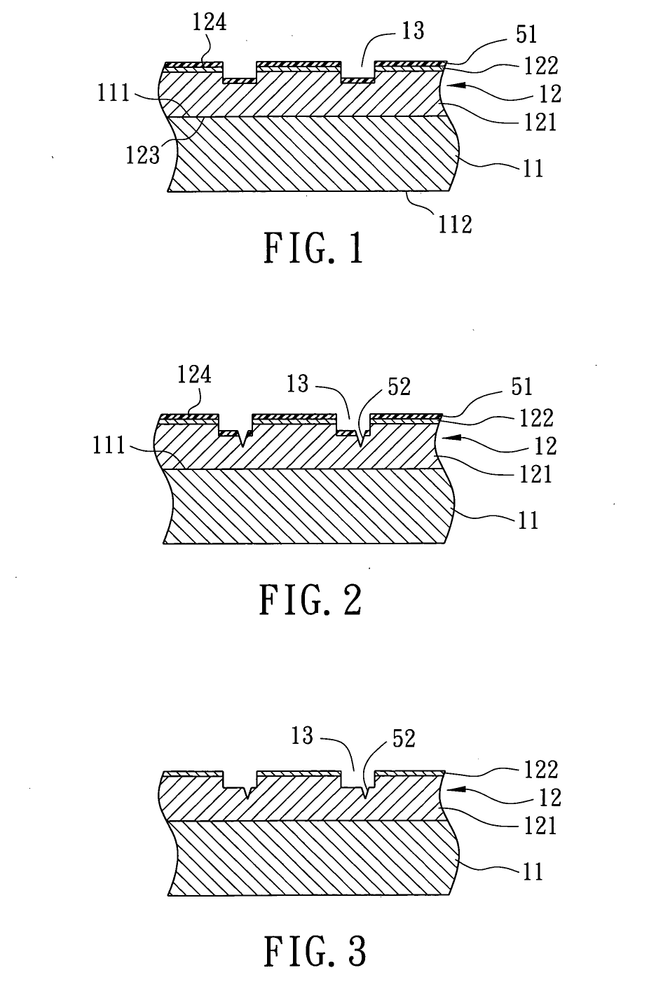

FIGS. 1 to 8 illustrate consecutive steps of the preferred embodiment of a method for dicing a light emitting diode (LED) semiconductor wafer according to the present invention. The semiconductor wafer has a substrate 11 and an integrated circuit layer 12 formed on the substrate 11. The substrate 11 has opposite inner and outer surfaces 111, 112. The integrated circuit layer 12 has an inner surface 123 attached to the inner surface 111 of the substrate 11, and an outer surface 124 opposite to the inner surface 123 of the integrated circuit layer 12, and includes an epitaxial sub-layer 121 grown on the inner surface 111 of the substrate 11, and a transparent conductive layer 122 that defines the outer surface 124 of the integrated circuit layer 12. The epitaxial sub-layer 121 contains p-type and n-type semiconductor regions and an active region (not shown) for emitting light when actuated.

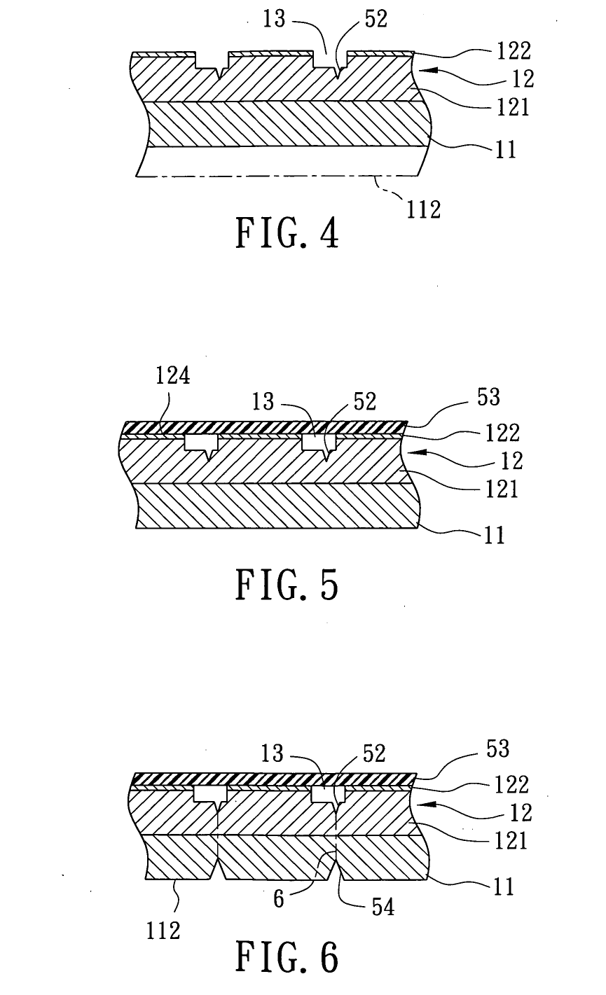

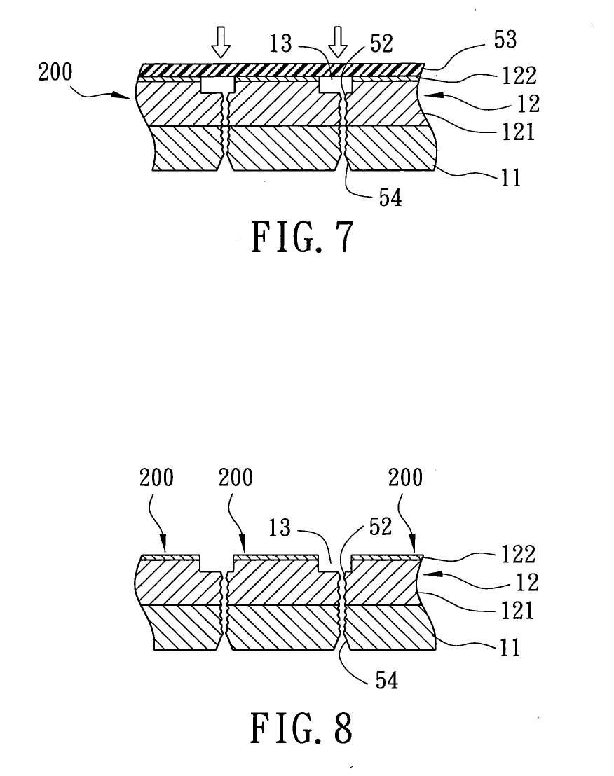

The method of this embodiment includes the steps of: forming elongated grooves 13 (see FIG. 1) that are indented from the outer surface 124 of the integrated circuit layer 12 in a transverse direction relative to the semiconductor wafer, each of the elongated grooves 13 being defined by a groove-defining wall; forming a photoresist layer 51 (see FIG. 1) on the outer surface 124 of the integrated circuit layer 12; forming elongated first notches 52 (see FIG. 2), each of which extends through the photoresist layer 51 and is further indented from the groove-defining wall of a respective one of the grooves 13 in the transverse direction such that each of the first notches 52 is spaced apart from the inner surface 111 of the substrate 11 by a predetermined thickness; removing the photoresist layer 51 from the semiconductor wafer 12 (see FIG. 3); thinning the substrate 11 from the outer surface 112 of the substrate 11 (see FIG. 4); attaching a blue tape 53 to the outer surface 124 of the integrated circuit layer 12 (see FIG. 5; forming elongated second notches 54, each of which is indented from the outer surface 112 of the thinned substrate 11 in the transverse direction and each of which is registered with a respective one of the first notches 52 in the transverse direction such that the first and second notches 52, 54 cooperatively define imaginary breaking lines 6, respectively (see FIG. 6); pressing the blue tape 53 at positions that are aligned with the imaginary breaking lines 6, respectively, so as to break the semiconductor wafer into dices 200 (see FIG. 7); and removing the blue tape 53 from to separate the dices 200 (see FIG. 8). Unlike the shapes of the trenches formed on the integrated circuit layer and the substrate of the aforesaid conventional semiconductor wafer, each of the first notches 52 has a V-shaped cross-section, and each of the second notches 54 has an inverted V-shaped cross-section so as to permit sharp cleaving of the semiconductor wafer along the imaginary breaking lines 6 to reduce the extent of formation of cracks propagating along edges of the dices 200 thus formed.

In this embodiment, the integrated circuit layer 12 has a layer thickness of about 5 μm. Preferably, the total depth of each of the elongated grooves 13 and the respective one of the first notches 52 is less than 4 μm, and the width of a top opening of the V-shaped cross-section of each of the first notches 52 is about 5 μm. The depth of each of the second notches 54 is about 20 μm, and the width of a bottom opening of the V-shaped cross-section of each of the second notches 54 is about 15 μm. With the aforesaid dimensions and shapes of the first and second notches 52, 54, the width of each of the elongated grooves 13 can be reduced to less than 30 μm, and the dimensions of each of the dices together with the elongated grooves 13 therearound can be reduced from 355×355 μm² (for conventional dicing methods) to 325×325 μm², thereby increasing the density of the dices 200 on the semiconductor wafer. Moreover, the LED dices 200 thus formed have a higher luminance (up to 15% higher) and a higher yield (improvement from 80% to 95%) as compared to LED dices formed from the conventional dicing methods.

With the shapes and dimensions of the first and second notches 52, 54, the aforesaid drawbacks associated with the prior art can be alleviated.

With the invention thus explained, it is apparent that various modifications and variations can be made without departing from the spirit of the present invention. It is therefore intended that the invention be limited only as recited in the appended claims.

What is claimed is:

1. A method for dicing a semiconductor wafer having a substrate and an integrated circuit layer formed on the substrate, the substrate having opposite inner and outer surfaces, the integrated circuit layer having an inner surface attached to the inner surface of the substrate, and an outer surface opposite to the inner surface of the integrated circuit layer, the method comprising:
forming elongated grooves that are indented from the outer surface of the integrated circuit layer in a transverse direction relative to the semiconductor wafer, each of the elongated grooves being defined by a groove-defining wall;
forming a photoresist layer on the outer surface of the integrated circuit layer;
forming elongated first notches, each of which extends through the photoresist layer and is further indented from the groove-defining wall of a respective one of the grooves in the transverse direction such that each of the first notches is spaced apart from the inner surface of the substrate by a predetermined thickness;
removing the photoresist layer from the semiconductor wafer;
thinning the substrate from the outer surface of the substrate;
attaching a blue tape to the outer surface of the integrated cirucit layer;
forming elongated second notches, each of which is indented from the outer surface of the thinned substrate in the transverse direction and each of which is registered with a respective one of the first notches in the transverse direction such that the first and second notches cooperatively define imaginary breaking lines, respectively; and
pressing the blue tape at positions that are aligned with the imaginary breaking lines, respectively, so as to break the semiconductor wafer into dices;
wherein each of the first notches has a V-shaped cross-section, and each of the second notches has an inverted V-shaped cross-section so as to permit sharp cleaving of the semiconductor wafer along the imaginary breaking lines to reduce the extent of formation of cracks propagating along edges of the dices thus formed.
